(19) United States
(12) Patent Application Publication
(10) Pub. No.: US 2006/0202920 A1
(43) Pub. Date: Sep. 14, 2006

(54) Display and array substrate

(76) Inventor: Makoto Shibusawa, Fukaya-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/363,048

(22) Filed: Feb. 28, 2006

(30) Foreign Application Priority Data
Mar. 8, 2005 (JP) 2005-064127

(51) Int. Cl. G09G 3/30

(52) U.S. Cl. 345/76

(57) ABSTRACT

A display includes a substrate and pixels arranged in a matrix form on the substrate. Each of the pixels includes a display element and first and second field-effect transistors equal in conduction type to each other. The display element and the first field-effect transistor are electrically connected in series between first and second power supply terminals. A source of the second field-effect transistor is electrically connected to a gate of the first field-effect transistor. The first field-effect transistor is deeper in threshold voltage than the second field-effect transistor.

### CROSS-REFERENCE TO RELATED APPLICATIONS

This application is based upon and claims the benefit of priority from prior Japanese Patent Application No. 2005-064127, filed Mar. 8, 2005, the entire contents of which are incorporated herein by reference.

### BACKGROUND OF THE INVENTION

1. Field of the Invention

The present invention relates to a display and an array substrate.

2. Description of the Related Art

An organic electroluminescent (EL) display controls the optical characteristics of a display element using a drive current passed through the element. Various structures can be adopted for pixels in such a display. For example, U.S. Pat. No. 6,373,454 describes an organic EL display in which each pixel circuit includes a current mirror.

In an active matrix display in which a drive current is passed through the display element as typified by the organic EL display, a field effect transistor (FET) is used as a drive control element. A gate of the field effect transistor and a video signal line are connected together via at least one switch. The switch is also composed of FET.

During a write period, the switch is closed and a video signal is supplied to the gate of the drive control element. During a subsequent retention period, the switch is opened and the gate-to-source voltage of the drive control element is maintained at a fixed value. The drive control element controls the drive current passing through the display element so that the magnitude of the drive current corresponds to the gate-to-source voltage.

The switch is normally formed on an insulator such as a glass substrate. A threshold voltage thus varies among different switches. Consequently, if, for example, a p-channel FET is used as the switch, a high voltage needs to be applied to the gate of the p-channel FET as an off signal to close the switch, in order to prevent the gate-to-source voltages of the switches in all the pixels from falling within a sub-threshold region during the retention period. However, the off signal desirably has a low voltage in order to prevent the dielectric breakdown of the p-channel FET or a slow trapping phenomenon.

### BRIEF SUMMARY OF THE INVENTION

An object of the present invention is to allow FET connected to a gate of a drive control element to exhibit an excellent off characteristic and to prevent the dielectric breakdown of FET and a slow trapping phenomenon.

According to a first aspect of the present invention, there is provided a display comprising a substrate and pixels arranged in a matrix form on the substrate, wherein each of the pixels comprises a display element, a first field-effect transistor, the display element and the first field-effect transistor being electrically connected in series between first and second power supply terminals, and a second field-effect transistor whose source is electrically connected to a gate of the first field-effect transistor, the first and second field-effect transistors being equal in conduction type to each other, and the first field-effect transistor being deeper in threshold voltage than the second field-effect transistor.

According to a second aspect of the present invention, there is provided a display comprising a substrate and pixels arranged in a matrix form on the substrate, wherein each of the pixels comprises a display element, a first field-effect transistor, the display element and the first field-effect transistor being electrically connected in series between first and second power supply terminals, and a second field-effect transistor whose source is electrically connected to a gate of the first field-effect transistor, the first and second field-effect transistors being equal in conduction type to each other, and the first field-effect transistor being larger in channel length than the second field-effect transistor.

According to a third aspect of the present invention, there is provided a display comprising a substrate and pixels arranged in a matrix form on the substrate, wherein each of the pixels comprises a display element, a first field-effect transistor, the display element and the first field-effect transistor being electrically connected in series between first and second power supply terminals, and a second field-effect transistor whose source is electrically connected to a gate of the first field-effect transistor, the first and second field-effect transistors being equal in conduction type to each other, and wherein of the first and second field-effect transistors, only the first field-effect transistor includes a channel doped with impurities which makes threshold voltage deeper.

According to a fourth aspect of the present invention, there is provided a display comprising a substrate and pixels arranged in a matrix form on the substrate, wherein each of the pixels comprises a display element, a first field-effect transistor, the display element and the first field-effect transistor being electrically connected in series between first and second power supply terminals, and a second field-effect transistor whose source is electrically connected to a gate of the first field-effect transistor, the first and second field-effect transistors being equal in conduction type to each other, and wherein of the first and second field-effect transistors, only the second field-effect transistor includes a channel doped with impurities which makes threshold voltage shallower.

According to a fifth aspect of the present invention, there is provided an array substrate comprising a substrate and pixel circuits arranged in a matrix form on the substrate, wherein each of the pixel circuits comprises a pixel electrode, a first field-effect transistor electrically connected between a power supply terminal and the pixel electrode, and a second field-effect transistor whose source is electrically connected to a gate of the first field-effect transistor, the first and second field-effect transistors being equal in conduction type to each other, and the first field-effect transistor being deeper in threshold voltage than the second field-effect transistor.

### BRIEF DESCRIPTION OF THE SEVERAL VIEWS OF THE DRAWING

FIG. 1 is a plan view schematically showing a display according to an embodiment of the present invention;

FIG. 2 is a sectional view showing an example of a structure that can be adopted for the display in FIG. 1;

FIG. 3 is a timing chart schematically showing an example of a method for driving the display shown in FIG. 1;

FIG. 4 is a sectional view schematically showing an example of a structure that can be adopted for the drive control element; and

FIG. 5 is a sectional view schematically showing an example of a structure that can be adopted for the diode connection switch.

### DETAILED DESCRIPTION OF THE INVENTION

Embodiments of the present invention will be described below in detail with reference to the drawings. In the drawings, the same reference numerals denote components proving similar functions. Duplicate descriptions will be omitted.

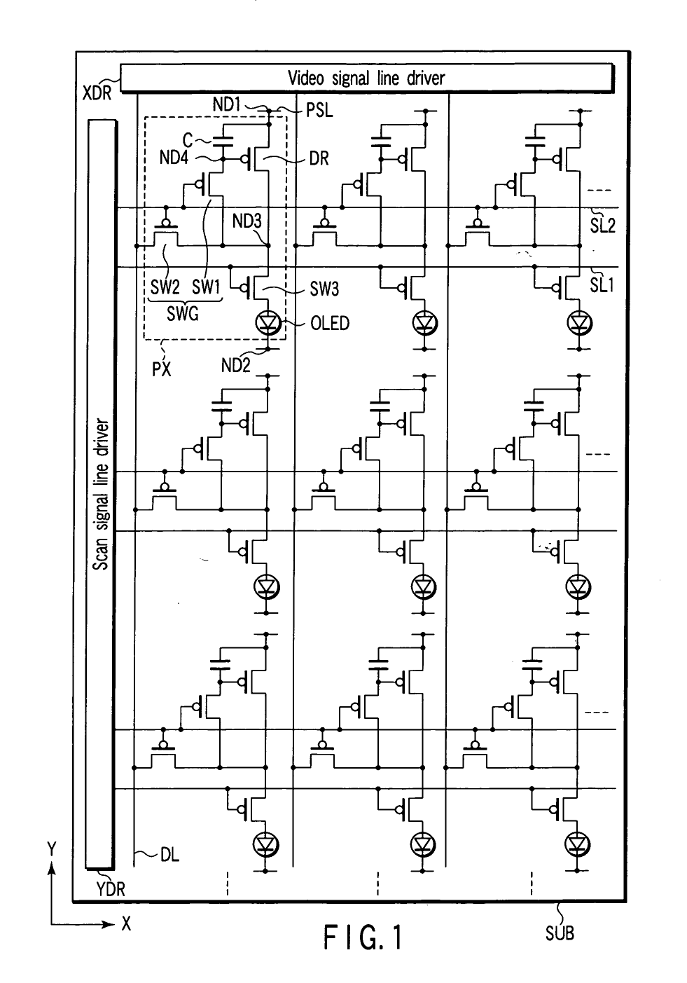

FIG. 1 is a plan view schematically showing a display in accordance with an embodiment of the present invention.

The display in FIG. 1 is an active matrix organic EL display that adopts an active matrix driving method. The display includes a plurality of pixels PX. The pixels are arranged in a matrix on an insulating substrate SUB, for example, a glass substrate.

A video signal line driver XDR and a scan signal line driver YDR are arranged on the substrate SUB.

Scan lines SL1 and SL2 extend along the rows of the pixels PX, i.e., in an X direction, and are arranged on the substrate SUB in a Y direction along the columns of the pixels PX. The scan signal lines SL1 and SL2 are connected to the scan signal line driver YDR, which supplies a scan signal as a voltage signal.

Video signal lines extend in the Y direction and are arranged in the X direction. The video signal lines DL are connected to the video signal line driver XDR, which supplies a video signal as a current signal.

Power supply lines PSL are also arranged on the substrate SUB.

Each of the pixels PX includes a drive control element DR, a diode connection switch SW1, a video signal supply control switch SW2, an output control switch SW3, a capacitor C, and a display element OLED. The diode connection switch SW1 and the video signal supply control switch SW2 constitute a switch group SWG.

The display element OLED includes an anode and a cathode which face each other, and an active layer having optical characteristics varying depending on a current flowing between the anode and cathode. Here, by way of example, the display element OLED is an organic EL element including, as an active layer, a light-emitting layer made of organic material. By way of example, the anode is a lower electrode formed like an island correspondently with the pixel PX, that is, a pixel electrode. By way of example, the cathode is an upper electrode which is common to all the pixels PX and which faces the lower electrode with the active layer interposed therebetween. In other words, the cathode is a common or counter electrode.

The drive control element DR is a thin film transistor (referred to as TFT below) having a source, a drain, and a channel formed in a semiconductor layer. Here, by way of example, the drive control element DR is composed of a p-channel TFT including a polycrystalline silicon layer as a semiconductor layer. A source of the drive control element DR is connected to the power source line PSL. A node ND1 on the power supply line PSL corresponds to a first power supply terminal.

The diode connection switch SW1 is connected between the gate and drain of the drive control element DR. A switching operation of the diode connection switch SW1 is controlled by, for example, a scan signal supplied by the scan signal line driver YDR via the scan signal line SL2. Here, by way of example, the diode connection switch SW1 is composed of a p-channel TFT having a gate connected to the scan signal line SL2 and a source and a drain connected to the gate and drain, respectively, of the drive control element DR.

The video signal supply control switch SW2 is connected between the drain of the drive control element DR and the video signal line DL. A switching operation of the video signal supply control switch SW2 is controlled by, for example, a scan signal supplied by the scan signal line driver YDR via the scan signal line SL2. Here, by way of example, the video signal supply control switch SW2 is composed of a p-channel TFT having a gate connected to the scan signal line SL2 and a source and a drain connected to the drain of the drive control element DR and the video signal line DL, respectively.

The output control switch SW3 and the display element OLED are connected in series between the drain of the drive control element DR and a node ND2. The node ND2 corresponds to a second power supply terminal. Here, the output control switch SW3 is composed of a p-channel TFT having a gate connected to the scan signal line SL1 and a source and a drain connected to the drain of the drive control element DR and the anode of the display element OLED, respectively. The second power supply terminal ND2 has a lower potential than the first power supply terminal ND1.

The capacitor C is connected between a constant potential terminal and the gate of the drive control terminal DR. Here, by way of example, the capacitor C is connected between the node ND1 and the gate of the drive control element DR. The capacitor C serves to maintain the gate-to-source voltage of the drive control element DR at an almost fixed value during a display period following a write period.

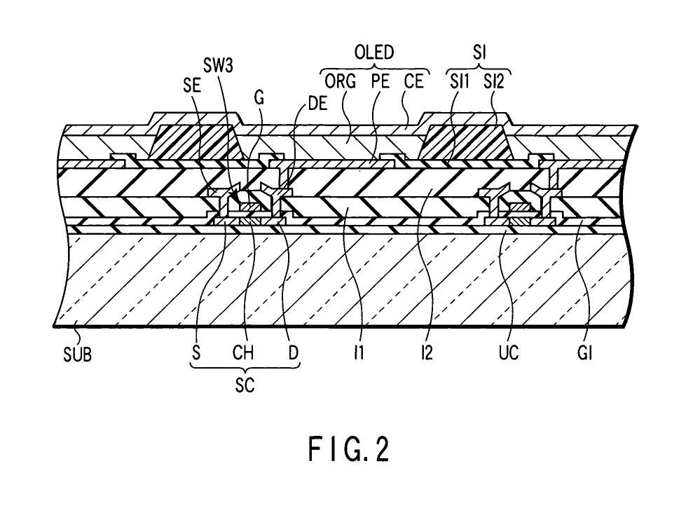

FIG. 2 is a sectional view showing an example of a structure that can be adopted for the display in FIG. 1. FIG. 2 shows only the output control switch SW3 as TFT, the diode connection switch SW1 and the video signal supply control switch SW2 each have a structure similar to that of the output control switch SW3. The drive control element DR also has a structure similar to that of the output control switch SW3.

As shown in FIG. 2, an undercoat layer UC is formed on a major surface of the insulating substrate SUB. For example, a stack of an SiNₓ layer and an SiO₂ layer may be used as the undercoat layer UC.

A patterned polycrystalline silicon layer is placed on the undercoat layer UC as semiconductor layers SC. The source S and drain D of TFT are formed in each semiconductor layer SC so as to be separated from each other. The region CH between the source and drain D in the semiconductor layer SC is used as a channel.

A gate insulator GI is formed on the semiconductor layer SC. A first conductor pattern and an insulating film I1 are sequentially formed on the gate insulator GI. The first conductor pattern is utilized as gates G of TFTs, first electrodes (not shown) of the capacitors C, the scan signal lines SL1 and SL2, wiring connecting them together, and the like. The insulating film I1 is utilized as an interlayer insulating film and a dielectric layer of the capacitor C.

A second conductor pattern is formed on the insulating film I1. The second conductor pattern is utilized as source electrodes SE, drain electrodes DE, second electrodes (not shown) of the capacitors C, the video signal lines DL, the power supply lines PSL, wiring connecting them together, and the like. The source electrode SE and the drain electrode DE are connected to the source S and drain D, respectively, of TFT at through-holes formed in the insulating films GI and I1.

An insulating film I2 and a third conductor pattern are sequentially formed on the second pattern and insulating film I1. The insulating film I2 is utilized as a passivation film and/or a flattened layer. The third conductor pattern is utilized as a pixel electrode PE in each organic EL element OLED. Here, by way of example, the pixel electrode PE is an anode.

The insulating film I2 has a through-hole formed for each pixel PX and which is in communication with the drain electrode DE, connected to the drain D of the output control switch SW3. Each pixel electrode PE covers a sidewall and a bottom surface of the through-hole and is thus connected to the drain D of the output control switch SW3 via the drain electrode DE.

A partition insulating layer SI is formed on the insulating film I2. Here, by way of example, the partition insulating layer SI is composed of a stack of an organic insulating layer SI1 and an organic insulating layer SI2. However, the organic insulating layer SI1 may be omitted.

Through-holes are formed in the partition insulating layer SI at the positions of the pixel electrodes PE. In each through-hole in the partition insulating layer SI, an organic layer ORG including a light-emitting layer covers the pixel electrode PE. The light-emitting layer is, for example, a thin film containing a luminescent organic compound that emits a red, green, or a blue light. The organic layer ORG may includes, for example, a hole injection layer, a hole transporting layer, an electron injection layer, and an electron transporting layer in addition to the light-emitting layer. The layers constituting the organic layer ORG can be formed by, for example, a mask deposition method or an ink jet method.

A common electrode CE is formed on the partition insulating layer SI and organic layers ORG. The common electrode CE is electrically connected to electrode wire providing the node ND2, via a contact hole (not shown) formed in the insulating layer I1, insulating layer I2, and partition insulating layer SI. Here, by way of example, the common electrode CE is a cathode.

Each organic EL element OLED is composed of the pixel electrode PE, organic layer ORG, and common electrode CE.

In this display, an array substrate is composed of the substrate SUB, the pixel electrode PE, and members interposed between them. The array substrate may further include the partition insulating layer SI, the scan signal line driver YDR, and the video signal line driver XDR.

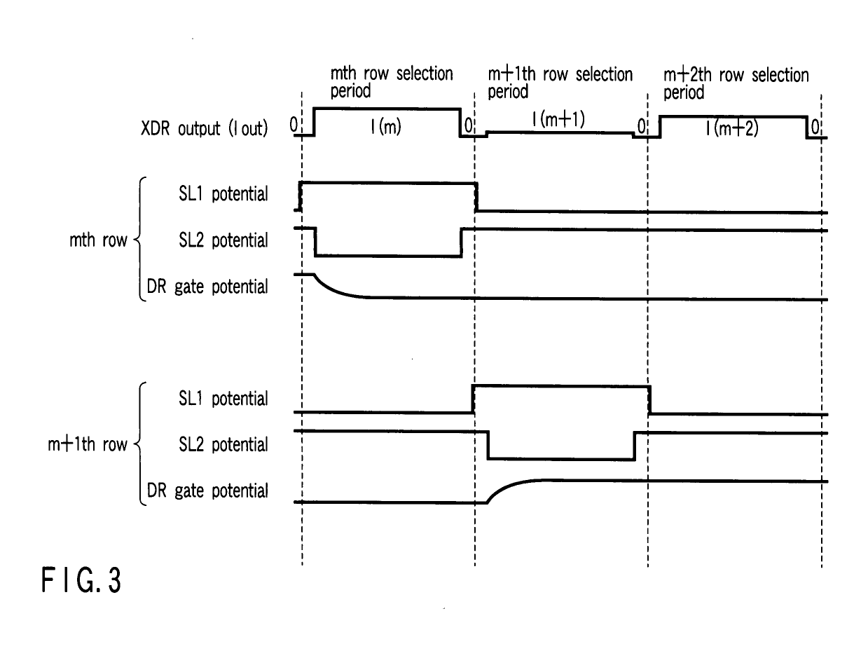

FIG. 3 is a timing chart schematically showing an example of a method for driving the display shown in FIG. 1.

In FIG. 3, the abscissa indicates time, and the ordinate indicates potential or magnitude of current. In FIG. 3, a waveform shown as a “XDR output (Iₒᵤₜ)” indicates a current passed through the video signal line DL by the video signal line driver XDR. Waveforms shown as an “SL1 potential” and an “SL2 potential” indicate the potentials of the scan signal lines SL1 and SL2. A waveform shown as a “DR gate potential” indicates the gate potential of the drive control element DR.

With the method shown in FIG. 3, the display in FIG. 1 is driven by the method described below.

When a certain gray level is to be displayed on one of the pixels PX in the m-th row, during a period in which the pixels PX in the m-th row are selected, that is, during an m-th row selection period, the potential of the scan signal line SL1 is first changed from a second potential that turns on the switch SW3 to a first potential that turns off the switch SW3 to open the switch SW3 (nonconductive state), for example. During a write period with the switch SW3 open, a write operation described below is performed.

First, for example, the potential of the scan signal line SL2 is changed from a third potential that turns off the switches SW1 and SW2 to a fourth potential that turns on the switches SW1 and SW2 to close the switches SW1 and SW2 (conductive state). This connects the gate of the drive control element DR, the drain of the drive control element DR, and the video signal line DL together.

Then, the video signal line driver XDR supplies a video signal to the selected pixel PX via the video signal line DL. That is, the video signal line driver XDR passes a current Iₒᵤₜ from the power supply terminal ND1 to the video signal line DL. The magnitude of the current Iₒᵤₜ corresponds to a drive current to be passed through the display element OLED of the selected pixel PX, that is, a gray level to be displayed on the selected pixel PX. This write operation sets the gate potential of the drive control element DR at a value obtained when the current Iₒᵤₜ flows between the source and drain of the drive control element DR.

Then, the potential of the scan signal line SL2 is changed from the fourth potential to the third potential to open the switches SW1 and SW2 (nonconductive state). That is, the gate of the drive control element DR, the drain of the drive control element DR, and the video signal line DL are disconnected from one another. Subsequently, the potential of the scan signal line SL1 is changed from the first potential to the second potential to close the switch SW3 (conductive state).

As described above, the write operation sets the gate potential of the drive control element DR at the value obtained when the current Iₒᵤₜ flows. This gate potential is maintained until the switches SW1 and SW2 are closed. Consequently, during an effective display period with the switch SW3 closed, a drive current having a magnitude corresponding to the current Iₒᵤₜ flows through the display element OLED, which thus displays a gray level corresponding to the magnitude of the drive current.

In the present embodiment, the threshold voltage of the drive control element DR is set at a sufficiently deep level. Here, the drive control element DR is deeper in threshold voltage than the diode connection switch SW1. As described below, this makes it possible to prevent the gate-to-source voltage of the diode connection switch SW1 from falling within the sub-threshold region even if an off signal supplied to the gate of the diode connection switch SW1 has a relatively low voltage.

A turn-off operation of the diode connection switch SW1 is affected by the potential of the node ND4. Specifically, during the retention period, the lower potential of the node ND4 prevents the gate-to-source voltage of the diode connection switch SW1 from falling within the sub-threshold region even with the relatively low gate voltage of the diode connection switch SW1.

The potential of the node ND4 during the retention period is also affected by the threshold voltage of the drive control element DR. Specifically, the deeper the threshold voltage of the drive control element DR is set, the lower the potential of the node ND4 becomes. Since the drive control element DR is a p-channel TFT, the lower the threshold voltage is set, the lower the potential of the node ND4 during the retention period becomes.

Therefore, by setting the threshold voltage of the drive control element DR at a sufficiently deep level, for example, setting it deeper than the threshold voltage of the diode connection switch SW1, it is possible to prevent the gate-to-source voltage of the diode connection switch SW1 from falling within the sub-threshold region even if the off signal supplied to the gate of the diode connection switch SW1 has a relatively low voltage.

Note that the phrase “a threshold voltage of a transistor is deeper” means, for example, that the transistor has a lower threshold voltage in the case where the transistor is a p-channel field-effect transistor, and that the transistor has a higher threshold voltage in the case where the transistor is an n-channel field-effect transistor. Note also that the phrase “a threshold voltage of a transistor is shallower” means, for example, that the transistor has a higher threshold voltage in the case where the transistor is a p-channel field-effect transistor, and that the transistor has a lower threshold voltage in the case where the transistor is an n-channel field-effect transistor. Therefore, when two p-channel field-effect transistors each having a negative threshold voltage are to be compared, one of the transistors whose absolute value of the threshold voltage is larger is deeper in threshold voltage than the other. Similarly, when two n-channel field-effect transistors each having a positive threshold voltage are to be compared, one of the transistors whose absolute value of the threshold voltage is larger is deeper in threshold voltage than the other.

The absolute value of the difference between the threshold voltages of the drive control element DR and diode connection switch SW1 is, for example, between about 0.5 and 1.5V. Typically, the difference is approximately 1V.

A structure described below may be adopted in order to set the threshold voltage of the drive control element DR deeper than that of the diode connection switch SW1.

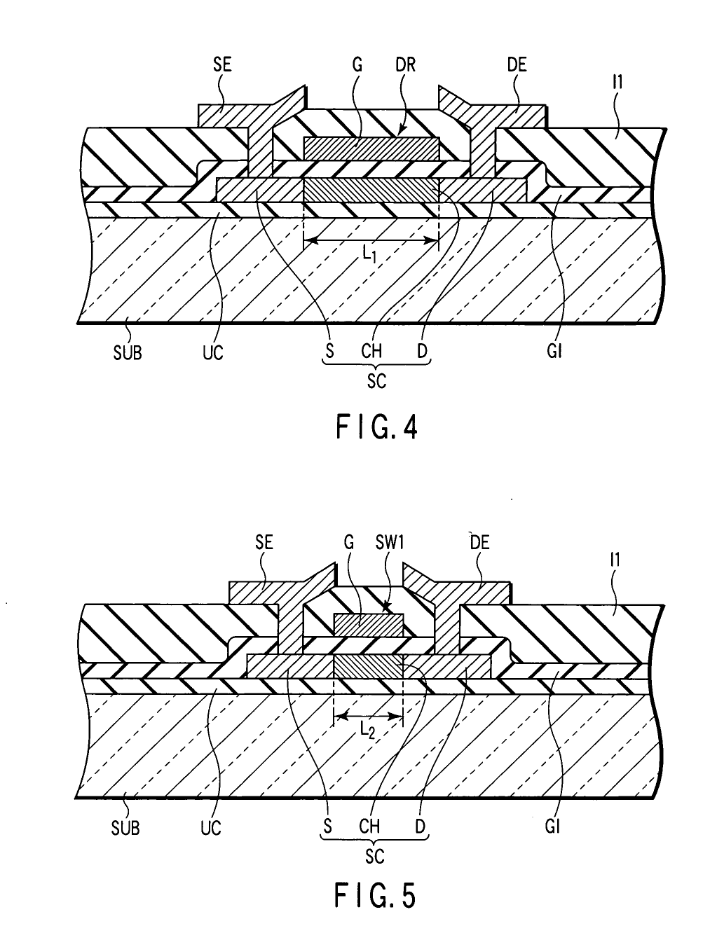

FIG. 4 is a sectional view schematically showing an example of a structure that can be adopted for the drive control element. FIG. 5 is a sectional view schematically showing an example of a structure that can be adopted for the diode connection switch.

The drive control element DR in FIG. 4 has a structure similar to that of the diode connection switch SW1 in FIG. 5 except for channel length. That is, the channel length L₁ of the drive control element DR in FIG. 4 is larger than the channel length L₂ of the diode connection switch SW1 in FIG. 5. For example, the channel length L₁ is 12 μm and the channel length L₂ is 4.5 μm. Such a structure enables the threshold voltage of the drive control element DR to be set deeper than that of the diode connection switch SW1.

The ratio L₁/L₂ of the channel L₁ to the channel L₂ is, for example, between 2 and 5. This allows the absolute value of the difference between the threshold voltages of the drive control element DR and diode connection switch SW1 to be easily set within the above range. If a multi-gate structure is adopted for the diode connection switch SW1, the shortest channel length of the diode connection switch is the channel length L₂.

At least one of the video signal line driver XDR and scan signal line driver YDR may be formed on the substrate SUB. In other words, n-channel TFTs and/or p-channel TFTs included in the drivers may be at least partly formed on the substrate SUB. In this case, a channel doping technique for doping the channel of TFT with a small amount of impurities may be utilized to stabilize the characteristics of the TFTs included in the pixels PX and the drivers XDR and YDR. However, the channel doping technique may result in a doping amount unevenness, which may lead to a threshold voltage unevenness. It is thus desirable to avoid adopting the channel doping technique for the formation of the drive control element DR. This prevents a threshold voltage unevenness attributed to the adoption of the channel doping technique, that is, a display unevenness.

For example, a process described below may be adopted to set the threshold voltage of the drive control element DR deeper than that of the diode connection switch SW1.

For example, of the channels CH of the drive control element DR and the diode connection switch SW1, only the channel CH of the drive control element DR is doped with impurities that make the threshold voltage deeper. Since the drive control element DR is a p-channel FET, only the channel CH of the drive control element DR is doped with P ions using PH₃ as a material gas, for example. This makes it possible to set the threshold voltage of the drive control element DR deeper than that of the diode connection switch SW1.

Alternatively, of the channels CH of the drive control element DR and the diode connection switch SW1, only the channel CH of the diode connection switch SW1 is doped with impurities that make the threshold voltage shallower. Since the diode connection switch SW1 is a p-channel FET, only the channel CH of the diode connection switch SW1 is doped with B ions using B₂H₆ as a material gas, for example. This makes it possible to set the threshold voltage of the drive control element DR deeper than that of the diode connection switch SW1.

The techniques described above in conjunction with the setting of the threshold voltages can be combined together. For example, only the channel CH of the drive control element DR may be doped with impurities that make the threshold voltage deeper, whereas only the channel CH of the diode connection switch SW1 may be doped with impurities that make the threshold voltage shallower. Alternatively, the structures in FIGS. 4 and 5 may be adopted for the drive control element DR and diode connection switch SW1, respectively, with only the channel CH of the drive control element DR doped with impurities that make the threshold voltage deeper. Alternatively, the structures in FIGS. 4 and 5 may be adopted for the drive control element DR and diode connection switch SW1, respectively, with only the channel CH of the diode connection switch SW1 doped with impurities that make the threshold voltage shallower. Alternatively, the structures in FIGS. 4 and 5 may be adopted for the drive control element DR and diode connection switch SW1, respectively, with only the channel CH of the drive control element DR doped with impurities that make the threshold voltage of the drive control element DR deeper and with only the channel CH of the diode connection switch SW1 doped with impurities that make the threshold voltage of the diode connection switch SW1 shallower.

The organic EL display in which each pixel PX includes the current mirror circuit has been illustrated. However, another circuit may be adopted for the pixel PX. For example, a configuration in which a voltage signal is written as a video signal may be adopted in place of the configuration in which the current signal is written as a video signal.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A display comprising a substrate and pixels arranged in a matrix form on the substrate, wherein each of the pixels comprises:
a display element;
a first field-effect transistor, the display element and the first field-effect transistor being electrically connected in series between first and second power supply terminals; and
a second field-effect transistor whose source is electrically connected to a gate of the first field-effect transistor, the first and second field-effect transistors being equal in conduction type to each other, and the first field-effect transistor being deeper in threshold voltage than the second field-effect transistor.

2. The display according to claim 1, wherein the first field-effect transistor is larger in channel length than the second field-effect transistor.

3. The display according to claim 1, wherein of the first and second field-effect transistors, only the first field-effect transistor includes a channel doped with impurities which makes the threshold voltage deeper.

4. The display according to claim 1, wherein of the first and second field-effect transistors, only the second field-effect transistor includes a channel doped with impurities which makes the threshold voltage shallower.

5. The display according to claim 1, wherein the first field-effect transistor is larger in channel length than the second field-effect transistor, and
wherein of the first and second field-effect transistors, only the first field-effect transistor includes a channel doped with impurities which makes the threshold voltage deeper.

6. The display according to claim 1, wherein the first field-effect transistor is larger in channel length than the second field-effect transistor, and
wherein of the first and second field-effect transistors, only the second field-effect transistor includes a channel doped with impurities which makes the threshold voltage shallower.

7. The display according to claim 1, wherein of the first and second field-effect transistors, only the first field-effect transistor includes a channel doped with impurities which makes the threshold voltage, and only the second field-effect transistor includes a channel doped with impurities which makes the threshold voltage shallower.

8. The display according to claim 1, wherein the first field-effect transistor is larger in channel length than the second field-effect transistor, and
wherein of the first and second field-effect transistors, only the first field-effect transistor includes a channel doped with impurities which makes the threshold voltage deeper, and only the second field-effect transistor includes a channel doped with impurities which makes the threshold voltage shallower.

9. The display according to claim 1, wherein the display element is an organic EL element.

10. A display comprising a substrate and pixels arranged in a matrix form on the substrate, wherein each of the pixels comprises:
a display element;
a first field-effect transistor, the display element and the first field-effect transistor being electrically connected in series between first and second power supply terminals; and
a second field-effect transistor whose source is electrically connected to a gate of the first field-effect transistor, the first and second field-effect transistors being equal in conduction type to each other, and the first field-effect transistor being larger in channel length than the second field-effect transistor.

11. The display according to claim 10, wherein the display element is an organic EL element.

12. A display comprising a substrate and pixels arranged in a matrix form on the substrate, wherein each of the pixels comprises:
a display element;
a first field-effect transistor, the display element and the first field-effect transistor being electrically connected in series between first and second power supply terminals; and
a second field-effect transistor whose source is electrically connected to a gate of the first field-effect transistor, the first and second field-effect transistors being equal in conduction type to each other, and
wherein of the first and second field-effect transistors, only the first field-effect transistor includes a channel doped with impurities which makes threshold voltage deeper.

13. The display according to claim 12, wherein the display element is an organic EL element.

14. A display comprising a substrate and pixels arranged in a matrix form on the substrate, wherein each of the pixels comprises:
a display element;
a first field-effect transistor, the display element and the first field-effect transistor being electrically connected in series between first and second power supply terminals; and
a second field-effect transistor whose source is electrically connected to a gate of the first field-effect transistor, the first and second field-effect transistors being equal in conduction type to each other, and
wherein of the first and second field-effect transistors, only the second field-effect transistor includes a channel doped with impurities which makes threshold voltage shallower.

15. The display according to claim 14, wherein the display element is an organic EL element.

16. An array substrate comprising a substrate and pixel circuits arranged in a matrix form on the substrate, wherein each of the pixel circuits comprises:
a pixel electrode;
a first field-effect transistor electrically connected between a power supply terminal and the pixel electrode; and
a second field-effect transistor whose source is electrically connected to a gate of the first field-effect transistor, the first and second field-effect transistors being equal in conduction type to each other, and the first field-effect transistor being deeper in threshold voltage than the second field-effect transistor.
